(19) United States
(12) Patent Application Publication
(10) Pub. No.: US 2017/0170283 A1
(43) Pub. Date: Jun. 15, 2017

(54) III-NITRIDE STRUCTURES GROWN ON SILICON SUBSTRATES WITH INCREASED COMPRESSIVE STRESS

(71) Applicant: IQE, PLC, St. Mellons (GB)

(72) Inventors: Oleg Laboutin, South Easton, MA (US); Chen-Kai Kao, Lexington, MA (US); Chien-Fong Lo, Braintree, MA (US); Hugues Marchand, Somerville, MA (US); Rodney Pelzel, Emmaus, PA (US)

(21) Appl. No.: 15/369,643

(22) Filed: Dec. 5, 2016

Related U.S. Application Data
(60) Provisional application No. 62/265,927, filed on Dec. 10, 2015.

(51) Int. Cl. H01L 29/20; H01L 29/36; H01L 29/207; H01L 21/02; H01L 29/778; H01L 29/66

(52) U.S. Cl. CPC H01L 29/2003; H01L 29/7787; H01L 29/66431; H01L 29/207; H01L 21/0254; H01L 29/36

(57) ABSTRACT

A III-nitride structure can include a silicon substrate, a nucleation layer over the silicon substrate, and a carbon-doped buffer layer over the nucleation layer. The carbon-doped buffer layer can include a III-nitride material and a concentration of carbon that is greater than 1×10²⁰ cm⁻³. The III-nitride structure can include a III-nitride channel layer over the carbon-doped buffer layer and a III-nitride barrier layer over the III-nitride channel layer. The carbon doping to a carbon concentration greater than 1×10²⁰ cm⁻³ can increase the compressive stress in the III-nitride structure.

### CROSS-REFERENCE TO RELATED APPLICATIONS

This application claims priority to U.S. Provisional Application Ser. No. 62/265,927, filed Dec. 10, 2015, of which the entire contents are hereby incorporated by reference.

### FIELD OF THE INVENTION

The systems and methods described herein relate to epitaxial structures and methods for growing III-nitride structures grown on silicon substrates with increased compressive stress.

### BACKGROUND

In the following description, numerous details are set forth for the purpose of explanation. However, one of ordinary skill in the art will realize that the embodiments described herein may be practiced without the use of these specific details. In other instances, well-known structures and devices are shown in block diagram form so that the description will not be obscured with unnecessary detail.

III-nitride materials are semiconducting materials comprising nitrogen and one or more Group III elements. Common Group III elements used to form III-nitride materials include aluminum, gallium, and indium. III-nitride materials have large direct band gaps, making them useful for high-voltage devices, radio-frequency devices, and optical devices. Furthermore, because multiple Group III elements can be combined in a single III-nitride film in varying compositions, the properties of III-nitride films are highly tunable.

III-nitride materials can be grown using metal-organic chemical vapor deposition (MOCVD). In MOCVD, one or more Group III precursors react with a Group V precursor to deposit a III-nitride film on a substrate. Some Group III precursors include trimethylgallium (TMGa) as a gallium source, trimethylaluminum (TMA) as an aluminum source, and trimethylindium (TMI) as an indium source. Ammonia is a Group V precursor which can be used as a nitrogen source.

Deposition of III-nitride films on silicon (Si) substrate is a cost-efficient way to fabricate high-power, high-frequency electronic devices. One major obstacle in deposition of III-nitrides on Si is a generation of the tensile stress in the III-nitride films during the post-growth cool-down process due to a large thermal mismatch between the III-nitride films and Si. This tensile stress is undesirable because it creates cracks and defects in the III-nitride film.

### SUMMARY

Systems and methods are described herein for growing epitaxial III-nitride structures on silicon substrates with increased compressive stress. A III-nitride structure can include a silicon substrate, a nucleation layer over the silicon substrate, and a carbon-doped buffer layer over the nucleation layer. The carbon-doped buffer layer can include a III-nitride material and a concentration of carbon that is greater than 1×10²⁰ cm⁻³. The III-nitride structure can include a III-nitride channel layer over the carbon-doped buffer layer and a III-nitride barrier layer over the III-nitride channel layer.

An average dislocation density of the carbon-doped buffer layer can be less than 1×10¹² cm⁻². Each of the nucleation layer, the carbon-doped buffer layer, the III-nitride channel layer, and the III-nitride barrier layer can be epitaxial. The carbon-doped buffer layer can include AlₓGa₁₋ₓN, where 0≦x≦1.

The III-nitride structure can include a stress management layer between the nucleation layer and the carbon-doped buffer layer. The stress management layer can include a concentration of carbon that is greater than 1×10²⁰ cm⁻³. The stress management layer can include a multiple layer structure. The multiple layer structure can include alternating layers of AlₓGa₁₋ₓN and GaN, where 0≦x≦1.

The III-nitride channel layer can include GaN. The barrier layer can include AlₓGa₁₋ₓN, where 0≦x≦1. The nucleation layer can include a concentration of carbon that is greater than 1×10²⁰ cm⁻³.

The III-nitride structure can include a III-nitride back-barrier layer between the carbon-doped buffer layer and the III-nitride channel layer and a capping layer over the barrier layer. The back-barrier layer can include a concentration of carbon that is greater than 1×10²⁰ cm⁻³.

The carbon doping can increase the compressive stress in a III-nitride structure. An extrinsic source of carbon can be used for depositing the carbon-doped buffer layer. The extrinsic source of carbon can include a carbon hydride and/or a carbon halide. The extrinsic carbon doping can be combined with intrinsic carbon doping, using an intrinsic source of carbon. The intrinsic source of carbon can include the one or more metalorganic precursors, which can contain one or more Group III elements.

### BRIEF DESCRIPTION OF THE DRAWINGS

The above and other features of the present disclosure will be more apparent upon consideration of the following detailed description, taken in conjunction with the accompanying drawings in which:

FIG. 1 depicts a III-nitride structure, according to an illustrative implementation;

FIG. 2 depicts a III-nitride structure that includes a stress management layer, according to an illustrative implementation;

FIG. 3 depicts a III-nitride structure that includes a III-nitride back-barrier layer and a III-nitride capping layer, according to an illustrative implementation;

FIG. 4 depicts graphs showing x-ray rocking curves along two crystal reflections of a III-nitride structure grown on a Si substrate, according to an illustrative implementation;

FIG. 5 depicts a graph showing in-situ wafer curvature measurements taken during deposition of a III-nitride structure on a silicon substrate, according to an illustrative implementation; and

FIG. 6 depicts a flow chart of a method for depositing any of the III-nitride structures depicted in FIGS. 1, 2, and 3, according to an illustrative implementation.

### DETAILED DESCRIPTION

One way to reduce or eliminate the tensile stress generated during the III-nitride structure cool-down process is to accumulate a sufficient amount of compressive stress during a deposition of the structure.

Compressive stress in the nitride-based structures can be introduced using lattice mismatch between different nitride compounds. For instance, compressive stress is generated when a GaN epitaxial layer having a large lattice constant is grown directly on an AlₓGa₁₋ₓN (0≦x≦1) layer having a lattice constant that is smaller than the GaN layer. In spite of the stress relaxation in thick films, the compressive stress can be still harvested to counter-balance the thermal mismatch stress. Compressive stress can also be generated by a multiple layer AlₓGa₁₋ₓN/GaN (0≦x≦1) structure. As the quality of deposited layers determines (to a large extent) the performance of devices formed therefrom, references to compressive or tensile stress herein are understood to refer to the stress state of the deposited layers, not the stress state of the substrate.

III-nitride structures can be doped with carbon (C) by intrinsic and/or extrinsic doping methods. Intrinsic doping is performed by depositing the Group III element with a metal-organic precursor (an intrinsic source) under conditions which result in carbon from the precursor remaining in the deposited layer. Intrinsic doping with carbon is often used to give semi-insulating properties to the deposited III-nitride material. The C atoms in carbon-doped GaN form deep acceptor levels trapping free electrons. When GaN is carbon-doped to render it semi-insulating, a typical C atomic concentration is in the range of 1×10¹⁷-1×10¹⁹ cm⁻³.

Extrinsic doping is performed by introducing an additional carbon-containing precursor (an extrinsic source of carbon) along with the metal-organic and gas precursors into the deposition chamber. Extrinsic doping can yield carbon-doped GaN with higher carbon concentrations than are achievable with intrinsic doping. Under typical MOCVD growth conditions, the C atoms substitute for some of the nitrogen (N) atoms in the III-nitride crystal lattice. An example of typical MOCVD growth conditions includes a wafer temperature of 1000° C., a reactor pressure around 100 Torr, and typical V-III ratios. The covalent radius of C is about 77 pm, which is larger than that of N (70 pm). The crystal lattice of the III-nitride material expands and accumulates a compressive stress when C is substituted in the place of N.

To accumulate sufficient amount of compressive stress, the C atomic concentration in the III-nitride lattice has to be ≧2×10¹⁹ cm⁻³, ≧1×10²⁰ cm⁻³, ≧2×10²⁰ cm⁻³, ≧5×10²⁰ cm⁻³, or ≧8×10²⁰ cm⁻³. To achieve such high C concentrations, the C can be delivered into a MOCVD reactor using an extrinsic source together with the gallium (Ga), aluminum (Al) and nitrogen (N) precursors. Extrinsic doping can be also used in combination with intrinsic doping using group III element precursors. Carbon hydride gases such as methane, propane or butane and carbon halide sources such as carbon tetrachloride (CCl₄), carbon tetrabromide (CBr₄) or bromotrichloromethane (CBrCl₃) can be used as extrinsic sources of C. Metal-organic precursors for Group III elements such as trimethylgallium and trimethylaluminum can be used as intrinsic sources of C. The C doping can be used in one or more of a single GaN buffer layer, a stress management layer, a multiple layer structure, and other layers to combine with the effect of lattice mismatch to accumulate increased compressive stress. Fabricating the III-nitride structures described herein can include simultaneously delivering three or more different precursors into the MOCVD reactor while depositing the III-nitride structure. The different precursors can comprise one or more Group III precursors, a Group V precursor, and an extrinsic C precursor, respectively.

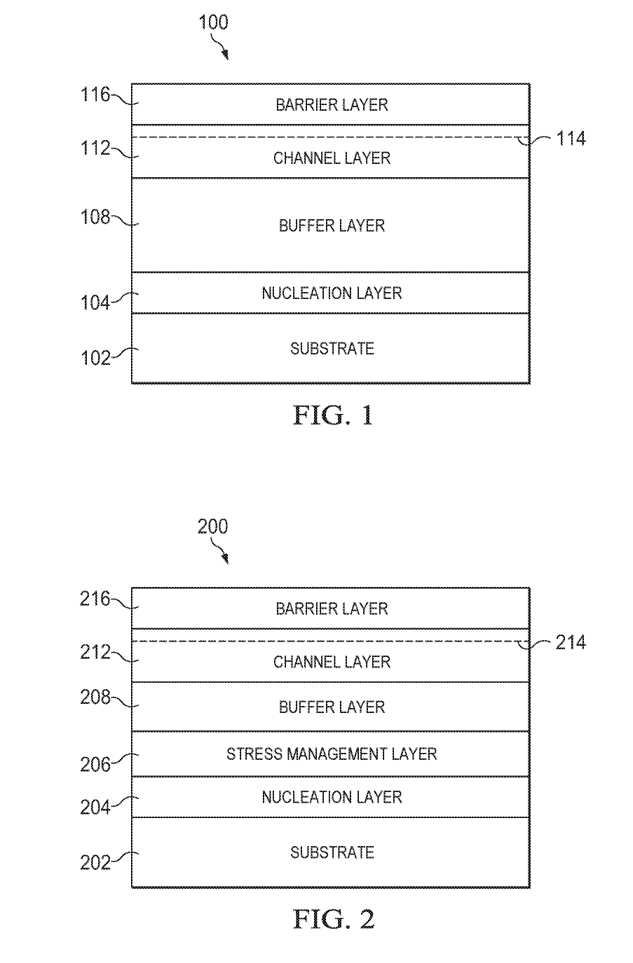

FIG. 1 depicts a III-nitride structure 100. The III-nitride structure 100 includes a (111) Si substrate 102, a nucleation layer 104 over the (111) Si substrate 102, a carbon-doped buffer layer 108 over the nucleation layer 104, a III-nitride channel layer 112 over the carbon-doped buffer layer 108, and a III-nitride barrier layer 116 over the III-nitride channel layer 112. A two-dimensional electron gas (2DEG) 114 is formed within the III-nitride channel layer 112 near the barrier-channel interface as a result of the piezo-electric and spontaneous polarization fields. Each of the layers 104, 108, 112, and 116 is epitaxial. Thus, the nucleation layer 104 is epitaxial with respect to the Si substrate 102, the carbon-doped buffer layer 108 is epitaxial with respect to the nucleation layer 104, the III-nitride channel layer 112 is epitaxial with respect to the carbon-doped buffer layer 108, and the III-nitride barrier layer 116 is epitaxial with respect to the III-nitride channel layer 112.

The nucleation layer 104 can comprise Si, SiC, SiN, AlN, BN, or other materials that can aid nucleation of III-nitride layers on (111) Si substrates. The carbon-doped buffer layer 108 can include one or more III-nitride materials such as GaN, AlₓGa₁₋ₓN (0≦x≦1), InₓAl_{y}Ga_{1-x-y}N (0≦x,y≦1), or another III-nitride material, that reduce density of the crystal defects in the structure and provide electrical insulation from the substrate. The carbon-doped buffer layer 108 can also be a multiple layer structure. The III-nitride channel layer 112 can include one or more III-nitride materials, such as GaN, InₓGa₁₋ₓN (0≦x≦1), or another III-nitride material, that provide room for a charge transfer in a lateral direction (via the 2DEG 114), parallel to the barrier-channel interface. The III-nitride barrier layer 116 can include one or more III-nitride materials, such as AlₓGa₁₋ₓN (0≦x≦1), InₓAl_{y}Ga_{1-x-y}N (0≦x,y≦1), or another III-nitride material, having a wider band-gap and smaller lattice constant compared to the III-nitride channel layer 112 and generating spontaneous polarization charges when in direct contact with the III-nitride channel layer 112. In this example, the compressive stress can be accumulated in the carbon-doped buffer layer 108 and III-nitride channel layer 112. The lattice mismatch between these layers and the nucleation layer 104 is used to accumulate the compressive stress. Doping of the carbon-doped buffer layer 108, and, optionally, the nucleation layer 104, with high C concentration can further increase the amount of the compressive stress in this structure. Carbon concentration in the carbon-doped buffer layer 108, and optionally the nucleation layer 104, can be ≧2×10¹⁹ cm⁻³, ≧1×10²⁰ cm⁻³, ≧2×10²⁰ cm⁻³, ≧5×10²⁰ cm⁻³, or ≧8×10²⁰ cm⁻³. The III-nitride channel layer 112 remains nominally undoped or unintentionally doped (UID). The effect of the C doping can be combined with that of the lattice mismatch or used separately.

Although the above description discloses III-nitride layers over a substrate that contains (111) Si, other material combinations are possible. The substrate can include one or more materials other than (111) Si. For example, the substrate can include one or more of (100) Si, sapphire, GaAs, GaN, InP, and other materials. The substrate can include a heterostructure between the nucleation layer and the III-nitride layer. The heterostructure may include multiple layers of different materials.

Examples of heterostructures include Si-on-insulator (SOI) and Si-on-sapphire (SOS) substrates. A nucleation layer could be grown over an SOI or an SOS substrate. The nucleation layer could be between the oxide layer and the Si layer, or above the Si layer, in an SOI or an SOS substrate. The Si layer of the SOI or SOS substrate could itself be the nucleation layer. The nucleation layer could be grown directly on the sapphire or handle wafer. A nucleation layer could be grown homogeneously with a layer of the same material but involved in a process similar to a heterostructure growth process, such as an epitaxial layer transfer process. In such an epitaxial layer transfer process, the epitaxial layer could comprise the nucleation layer.

FIG. 2 depicts a III-nitride structure 200 that includes a stress management layer. The layer structure 200 includes a (111) Si substrate 202, a nucleation layer 204 over the (111) Si substrate 202, a stress management layer 206 over the nucleation layer 204, a carbon-doped buffer layer 208 over the stress management layer 206, a III-nitride channel layer 212 over the carbon-doped buffer layer 208, and a III-nitride barrier layer 216 over the III-nitride channel layer 212. A two-dimensional electron gas (2DEG) 214 is formed within the III-nitride channel layer 212 near the barrier-channel interface as a result of the piezo-electric and spontaneous polarization fields. Each of the layers 204, 206, 208, 212, and 216 is epitaxial. Thus, the nucleation layer 204 is epitaxial with respect to the Si substrate 202, the stress management layer 206 is epitaxial with respect to the nucleation layer 204, the carbon-doped buffer layer 208 is epitaxial with respect to the stress management layer 206, the III-nitride channel layer 212 is epitaxial with respect to the carbon-doped buffer layer 208, and the III-nitride barrier layer 216 is epitaxial with respect to the III-nitride channel layer 212.

The stress management layer 206 reduces a density of crystal defects and builds a compressive stress into the layer structure 200 thus counter-acting the tensile stress generated due to the thermal mismatch between the III-nitride structure and Si substrate. The stress management layer 206 can comprise one or more of AlN, AlₓGa₁₋ₓN (0≦x≦1), InₓAl_{y}Ga_{1-x-y}N (0≦x,y≦1), GaN, and other III-nitride materials. It can comprise a single layer, multiple layers, super-lattices or other layer combinations. For example, the stress management layer 206 can comprise a carbon-doped multiple-layer structure. In some examples, the stress management layer 206 can comprise a transition layer and a carbon-doped multiple-layer structure, with the transition layer between the nucleation layer 204 and the carbon-doped multiple-layer structure. The carbon-doped multiple layer structure can include alternating layers of AlₓGa₁₋ₓN (0≦x≦1) and GaN, at least one of which is carbon-doped. The transition layer can comprise one or more of AlN, AlₓGa₁₋ₓN (0≦x≦1), InₓAl_{y}Ga_{1-x-y}N (0≦x,y≦1), GaN, and other III-nitride materials.

Compressive stress can be accumulated in the stress management layer 206, carbon-doped buffer layer 208, and III-nitride channel layer 212. The lattice mismatch between these layers and the nucleation layer can be used to accumulate the compressive stress. Doping one or more of the nucleation layer 204, the stress management layer 206, and the carbon-doped buffer layer 208 with high C concentration is used to increase the amount of the compressive stress in the III-nitride structure 200. Carbon concentrations in one or more of the layers 204, 206, and 208, including one or more sub-layers of these layers, can be ≧2×10¹⁹ cm⁻³, ≧1×10²⁰ cm⁻³, ≧2×10²⁰ cm⁻³, ≧5×10²⁰ cm⁻³, or ≧8×10²⁰ cm⁻³. The layers 204, 206, and 208, as well as any of their sub-layers, can have different carbon concentrations than other of the layers 204, 206, and 208 or other sub-layers of the layers 204, 206, and 208. The III-nitride channel layer 212 remains nominally undoped or UID. The effect of the C doping can be combined with that of the lattice mismatch or used separately.

The nucleation layer 204 can comprise Si, SiC, SiN, AlN, BN, or other materials that can aid nucleation of III-nitride layers on (111) Si substrates. The carbon-doped buffer layer 208 can include one or more III-nitride materials such as GaN, AlₓGa₁₋ₓN (0≦x≦1), InₓAl_{y}Ga_{1-x-y}N (0≦x,y≦1), or another III-nitride material, that reduce density of the crystal defects in the structure and provide electrical insulation from the substrate. The carbon-doped buffer layer 208 can also be a multiple layer structure. The III-nitride channel layer 212 can include one or more III-nitride materials, such as GaN, InₓGa₁₋ₓN (0≦x≦1), or another III-nitride material, that provide room for a charge transfer in a lateral direction (via the 2DEG 214), parallel to the barrier-channel interface. The III-nitride barrier layer 216 can include one or more III-nitride materials, such as AlₓGa₁₋ₓN (0≦x≦1), InₓAl_{y}Ga_{1-x-y}N (0≦x,y≦1), or another III-nitride material, having a wider band-gap and smaller lattice constant compared to the III-nitride channel layer 212 and generating spontaneous polarization charges when in direct contact with the III-nitride channel layer 212.

Although the above description discloses III-nitride layers over a substrate that contains (111) Si, other material combinations are possible. The substrate can include one or more materials other than (111) Si. For example, the substrate can include one or more of (100) Si, sapphire, GaAs, GaN, InP, and other materials. The substrate can include a heterostructure between the nucleation layer and the III-nitride layer. The heterostructure may include multiple layers of different materials.

Examples of heterostructures include Si-on-insulator (SOI) and Si-on-sapphire (SOS) substrates. A nucleation layer could be grown over an SOI or an SOS substrate. The nucleation layer could be between the oxide layer and the Si layer, or above the Si layer, in an SOI or an SOS substrate. The Si layer of the SOI or SOS substrate could itself be the nucleation layer. The nucleation layer could be grown directly on the sapphire or handle wafer. A nucleation layer could be grown homogeneously with a layer of the same material but involved in a process similar to a heterostructure growth process, such as an epitaxial layer transfer process. In such an epitaxial layer transfer process, the epitaxial layer could comprise the nucleation layer.

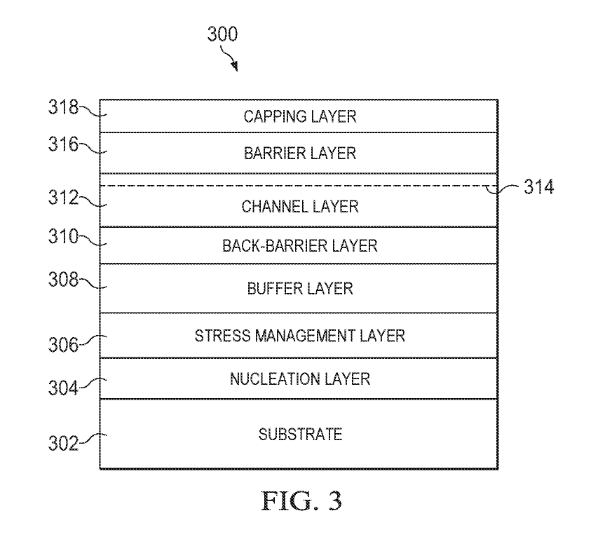

FIG. 3 depicts a III-nitride structure 300 that includes a III-nitride back-barrier layer and a III-nitride capping layer. The layer structure 300 includes a (111) Si substrate 302, a nucleation layer 304 over the (111) Si substrate 302, a stress management layer 306 over the nucleation layer 304, a carbon-doped buffer layer 308 over the stress management layer 306, a III-nitride back-barrier layer 310 over the carbon-doped buffer layer 308, a III-nitride channel layer 312 over the III-nitride barrier layer 310, a III-nitride barrier layer 316 over the III-nitride channel layer 312, and a capping layer 318 over the III-nitride barrier layer 316. A 2DEG 314 is formed within the III-nitride channel layer 312 near the barrier-channel interface as a result of the piezo-electric and spontaneous polarization fields. Each of the layers 304, 306, 308, 310, 312, 316, and 318 is epitaxial. Thus, the nucleation layer 304 is epitaxial with respect to the (111) Si substrate 302, the stress management layer 306 is epitaxial with respect to the nucleation layer 304, the carbon-doped buffer layer 308 is epitaxial with respect to the stress management layer 306, the III-nitride back-barrier layer 310 is epitaxial with respect to the carbon-doped buffer layer 308, the III-nitride channel layer 312 is epitaxial with respect to the III-nitride back-barrier layer 310, the III-nitride barrier layer 316 is epitaxial with respect to the III-nitride channel layer 312, and the capping layer 318 is epitaxial with respect to the III-nitride barrier layer 316.

The III-nitride back-barrier layer 310 creates a potential barrier on the side of III-nitride channel layer 312 opposite to the III-nitride barrier layer 316 and the 2DEG 314. This potential barrier prevents a leakage of free electrons from the 2DEG into the carbon-doped buffer layer 308. The III-nitride back-barrier layer 310 can include one or more III-nitride materials, such as GaN, AlₓGa₁₋ₓN (0≦x≦1), InₓAl_{y}Ga_{1-x-y}N (0≦x,y≦1), AlN, or another III-nitride material, having wider band-gaps compared to the material of the channel layer. In some examples, the III-nitride back-barrier layer 310 can include an InₓGa₁₋ₓN (0≦x≦1) material having a narrower band-gap compared to the material of the channel layer. In this case, the potential barrier is created due to the piezo-electric and spontaneous polarization fields.

The capping layer 318 stabilizes the top surface of the III-nitride layer structure 300 and increases a potential barrier for the Schottky contact of a HEMT fabricated using the III-nitride layer structure 300. The capping layer 318 can include one or more of GaN, AlN, SiN, Al₂O₃ or other III-nitride and passivating materials.

In this example, the compressive stress can be accumulated in the stress management layer 306, carbon-doped buffer layer 308, III-nitride back-barrier layer 310, and III-nitride channel layer 312. The lattice mismatch between these layers and the nucleation layer 304 is usually used to accumulate the compressive stress. Doping the stress management layer 306, carbon-doped buffer layer 308, and III-nitride back-barrier layer 310 with high C concentration can increase the amount of the compressive stress in this structure. Carbon concentrations in one or more of the layers 306, 308, and 310 can be ≧2×10¹⁹ cm⁻³, ≧1'10²⁰ cm⁻³, ≧2×10²⁰ cm⁻³, ≧5×10²⁰ cm⁻³, or ≧8×10²⁰ cm⁻³. The III-nitride channel layer 312 remains nominally undoped or UID. The effect of the C doping can be combined with that of the lattice mismatch or used separately.

The nucleation layer 304 can comprise Si, SiC, SiN, AlN, BN, or other materials that can aid nucleation of III-nitride layers on (111) Si substrates. The stress management layer 306 reduces a density of crystal defects and builds a compressive stress into the layer structure 300 thus counter-acting the tensile stress generated due to the thermal mismatch between the III-nitride structure and Si substrate. The stress management layer 306 can comprise one or more of AlN, AlₓGa₁₋ₓN (0≦x≦1), InₓAl_{y}Ga_{1-x-y}N (0≦x,y≦1), GaN, and other III-nitride materials. It can comprise a single layer, multiple layers, super-lattices or other layer combinations. For example, the stress management layer 306 can comprise a carbon-doped multiple-layer structure. In some examples, the stress management layer 306 can comprise a transition layer and a carbon-doped multiple-layer structure, with the transition layer between the nucleation layer 304 and the carbon-doped multiple-layer structure. The carbon-doped multiple layer structure can include alternating layers of AlₓGa₁₋ₓN (0≦x≦1) and GaN, at least one of which is carbon-doped. The transition layer can comprise one or more of AlN, AlₓGa₁₋ₓN (0≦x≦1), InₓAl_{y}Ga_{1-x-y}N (0≦x,y≦1), GaN, and other III-nitride materials.

The carbon-doped buffer layer 308 can include one or more III nitride materials, such as GaN, AlₓGa₁₋ₓN (0≦x≦1), InₓAl_{y}Ga_{1-x-y}N (0≦x,y≦1), or another III-nitride material, that reduce density of the crystal defects in the structure and provide electrical insulation from the substrate. The carbon-doped buffer layer 308 can also be a multiple layer structure. The III-nitride channel layer 312 can include one or more III-nitride materials, such as GaN, InₓGa₁₋ₓN (0≦x≦1), or another III-nitride material, providing room for a charge transfer in a lateral direction (via the 2DEG 314), parallel to the barrier-channel interface. The III-nitride barrier layer 316 can include one or more III-nitride materials, such as AlₓGa₁₋ₓN (0≦x≦1), InₓAl_{y}Ga_{1-x-y}N (0≦x,y≦1), or another III-nitride material, having a wider band-gap and smaller lattice constant compared to the III-nitride channel layer 312 and generating spontaneous polarization charges when in direct contact with the III-nitride channel layer 312.

Although the above description discloses III-nitride layers over a substrate that contains (111) Si, other material combinations are possible. The substrate can include one or more materials other than (111) Si. For example, the substrate can include one or more of (100) Si, sapphire, GaAs, GaN, InP, and other materials. The substrate can include a heterostructure between the nucleation layer and the III-nitride layer. The heterostructure may include multiple layers of different materials. Examples of heterostructures include rare earth oxide-on-Si (REO), Si-on-insulator (SOI) and Si-on-sapphire (SOS) substrates. A nucleation layer could be grown over an REO, SOI or an SOS substrate. A nucleation layer could be grown homogeneously with a layer of the same material but involved in a process similar to a heterostructure growth process, such as an epitaxial layer transfer process. In such an epitaxial layer transfer process, the epitaxial layer could comprise the nucleation layer.

The compressive stress generated by doping each layer is cumulative, so more compressive stress can be engineered by a higher carbon content throughout the stack. For this reason, it is desirable to carbon-dope all the layers of the structure stack below the III-nitride channel layer 112, 212 and 312 for the III-nitride layer structures 100, 200 and 300, respectively (not including the respective Si substrates). Carbon concentrations in each of the layers 108, 206, 208, 306, 308, and 310 can be ≧2×10¹⁹ cm⁻³, ≧1×10²⁰ cm⁻³, ≧2×10²⁰ cm⁻³, ≧5×10²⁰ cm⁻³, or ≧8×10²⁰ cm⁻³. Concentrations of dopants and other species are sometimes expressed in units of atoms-cm⁻³, but, more often, the name of the particle is omitted while referencing the same quantity and such concentrations are simply expressed in units of cm⁻³. Likewise, densities of defects are sometimes expressed in units of defects-cm⁻², but, more often, the name of the feature is omitted while referencing the same quantity and such concentrations are simply expressed in units of cm⁻². Such a defect density represents the areal density of defects in a plane parallel to the bottom surface of the substrate.

While the III-nitride layer structures 100, 200, and 300 can have compressive stress even if undoped, the carbon-doping of the layers 108, 206, 208, 306, 308, and 310 to carbon concentrations ≧2×10¹⁹ cm⁻³, ≧1×10²⁰ cm⁻³, ≧2×10²⁰ cm⁻³, ≧5×10²⁰ cm⁻³, or ≧8×10²⁰ cm⁻³ can increase the compressive stress beyond that which can be achieved without doping, allowing thicker buffer layers and reduced tensile stress after a post-synthesis structure cooling.

In some examples, the carbon concentration varies throughout one or more of the III-nitride layer structures 100, 200, and 300. In some examples, each layer of one or more of the III-nitride layer structures 100, 200, and 300 is carbon-doped to the highest practicable carbon concentration, and the carbon concentration sharply decreases to a minimal level just below the 2DEG 114, 214, and 314, respectively. Maintaining carbon concentrations at the highest practicable levels for each layer of the III-nitride structures 100, 200, and 300 results in the maximum compressive stress. Reducing the carbon concentration in the 2DEG 114, 214, and 314 is beneficial because the carbon dopants can act as deep level traps that trap and localize free electrons of the 2DEG 114, 214, and 314.

For an efficient compressive stress accumulation, the sources of tensile stress and paths of the compressive stress relaxation have to be suppressed. The various point defects and extended defects in III-nitride films can aid the tensile stress generation and compressive stress relaxation. One of the most common defects in III-nitride films is a threading dislocation. For compressive stress to be sustained in a III-nitride film, a density of threading dislocations in the film has to be sufficiently low. The density of threading dislocations can be estimated and controlled using x-ray diffraction (XRD) analysis.

The density of threading dislocations can be examined with XRD rocking curves taken along symmetric and asymmetric reflections of a III-nitride crystal lattice. In particular, the full width at half maximum (FWHM) of the relevant XRD rocking curve peak serves as a basic criteria. The FWHM of the peak refers to the width of the peak at one-half its maximum value. One or more rocking curve peaks can be detected by the XRD analysis for each material in a III-nitride layer structure. The relevant peak for the analysis described below will be the peak corresponding to the material and/or layer under analysis. Often, that peak will be a GaN or AlₓGa₁₋ₓN (0≦x≦1) peak corresponding to the buffer layer material. Threading dislocations in a material cause a broadening of the XRD rocking curve peaks and consequently an increase in their FWHM. The different types of dislocations (screw, edge or mixed types) affect peaks measured at different x-ray reflections. A combination of at least two rocking curves taken along different reflections can be used for dislocation density estimates.

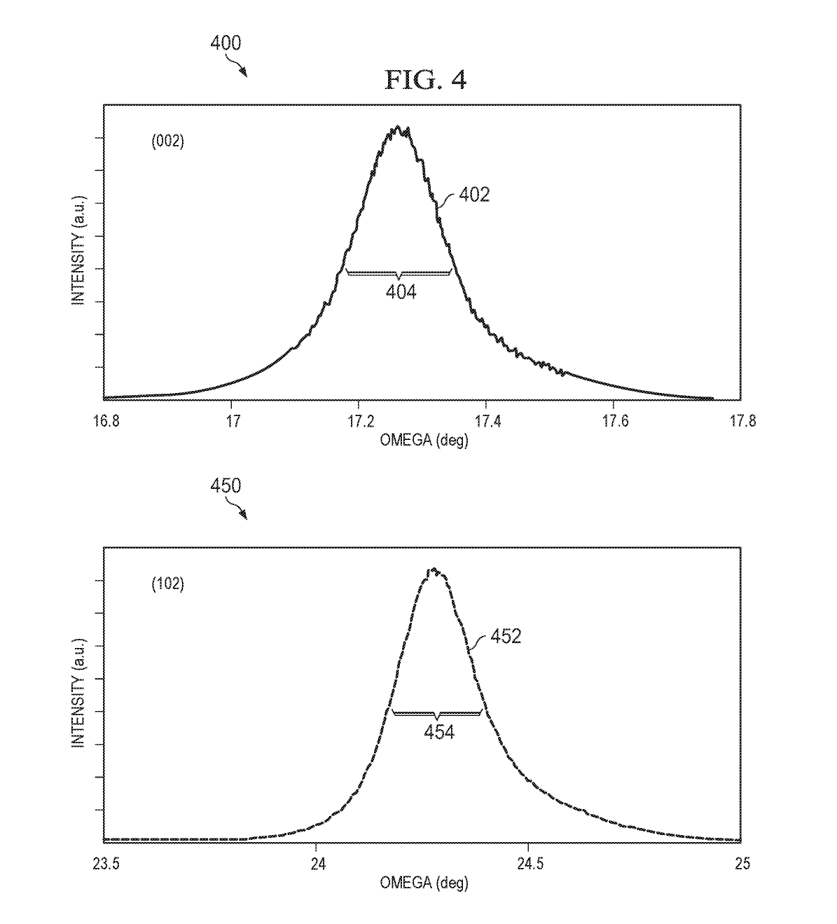

FIG. 4 depicts graphs 400 and 450 showing x-ray rocking curves along two reflections of a III-nitride layer structure grown on a (111) Si substrate. The thickness of the structure measured is approximately 4 μm. The graph 400 includes a rocking curve 402 taken along the (002) reflection and a rocking curve 452 taken along the (102) reflection. The rocking curve 402 has a FWHM 404, and the rocking curve 452 has a FWHM 454.

Doping a III-nitride material can lead to increased dislocation density in the III-nitride material, which can be determined by measuring the FWHM of an XRD rocking curve. To maintain acceptable quality of the overall III-nitride structure and compressive stress accumulation (and thus acceptable performance of devices fabricated using the III-nitride structure), average dislocation density should be maintained at sufficiently low levels (e.g., 10¹⁰-10¹¹ cm⁻², ≦10²⁰ cm⁻², ≦10⁹ cm⁻², ≦10⁸ cm⁻², or lower) even as carbon doping concentration increases to 10²⁰ cm⁻³ and above. Whether the average dislocation density of a III-nitride material has been maintained at sufficiently low levels, such as less than 1×10¹² cm⁻², and/or 10¹⁰-10¹¹ cm⁻², can be determined by measuring the FWHM of XRD rocking curves and comparing to expected values for the carbon doping concentration as described below. Because XRD has a penetration depth of several microns, XRD generates a signal from all material within its penetration depth. Thus, this technique results in an indication of the average dislocation density.

For a III-nitride layer structure with a carbon doping concentration of 10¹⁹ cm⁻³ or lower, the FWHM 404 can be approximately 600 arcsec, and the FWHM 454 can be approximately 800 arcsec. For a III-nitride layer structure with a carbon doping concentration of approximately 10²⁰ cm⁻³, the FWHM 404 can be approximately 700 arcsec, and the FWHM 454 can be approximately 950 arcsec. For a III-nitride layer structure with a carbon doping concentration of approximately 10²¹ cm⁻³, the FWHM 404 can be approximately 850 arcsec, and the FWHM 454 can be approximately 1200 arcsec.

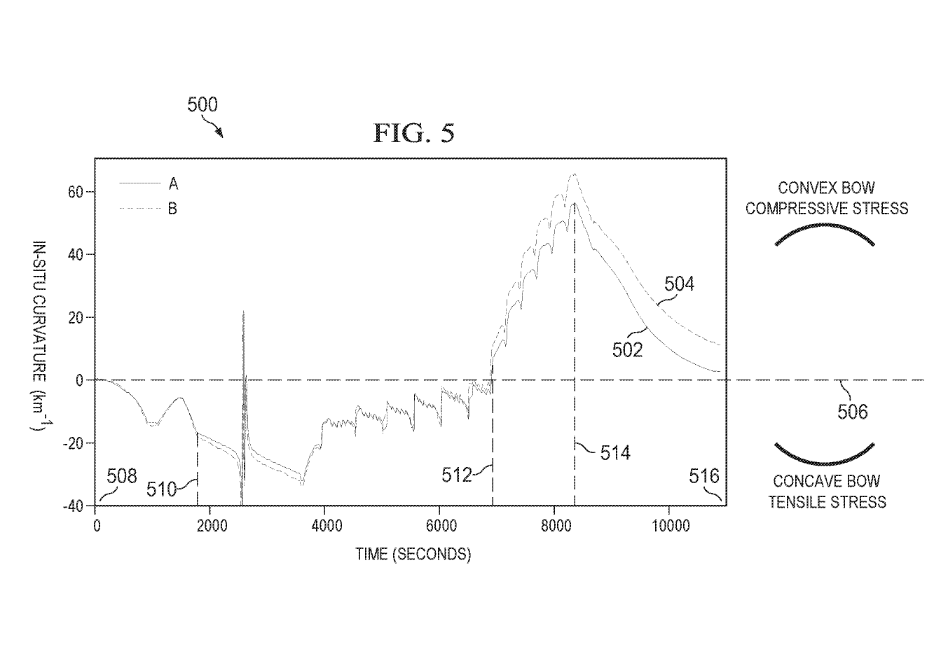

FIG. 5 depicts a graph 500 showing in-situ wafer curvature measurements taken during deposition of a III-nitride structure on a silicon substrate. The graph 500 includes a curve 502 measured on a first III-nitride layer structure (sample A) with a buffer layer C-doped to a doping concentration of 2×10¹⁹ cm⁻³. The graph 500 includes a curve 504 measured on a second III-nitride layer structure (sample B) with a buffer layer C-doped to a concentration of 1.5×10²⁰ cm⁻³. The graph 500 includes a zero curvature level 506. A curvature value above the zero curvature level 506 indicates that the wafer has a convex bow and compressive stress, and a curvature value below the zero curvature level 506 indicates that the wafer has a concave bow and tensile stress. The graph 500 also includes times 508, 510, 512, 514, and 516. Between times 508 and 510, the substrates were heated. Between times 510 and 512, the nucleation and stress management layers with AlN/GaN multiple-layer structure were grown over the substrates. Between times 512 and 514, a buffer layer was grown over the stress management layer. Between times 514 and 516, the layer structure was cooled.

The difference between the curves 502 and 504 illustrates the effect of C doping on the stress state of a III-nitride layer structure grown on a silicon substrate. At times 514 and 516, the wafer curvature is about 10 km⁻¹ more positive for sample B (curve 504) as compared to that for sample A (curve 502) indicating larger compressive stress accumulated in the layer with higher C concentration. In general, it is desirable to engineer the III-nitride structure such that the wafer has a significant convex bow at the end of the buffer layer growth (time 514) so that the wafer either has a slight convex bow or no bow at the end of the cool-down process (time 516).

This result is verified by ex-situ post-growth measurements of the wafer bow. While sample A (curve 502) has a post-growth wafer bow of 0 μm, sample B (curve 504) has a post-growth convex wafer bow of 12 μm. The larger convex wafer bow of sample B indicates larger compressive stress accumulated during the growth in sample B.

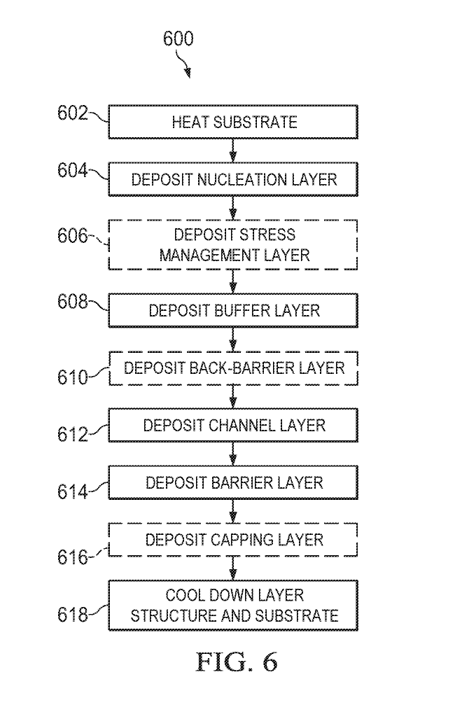

FIG. 6 depicts a flowchart of a method 600 for depositing any of the III-nitride structures 100, 200, and 300. At 602, a substrate (e.g., 102, 202, 302) is heated in a deposition system such as a vacuum chamber or other environmentally-controlled chamber. The substrate can be a Si (111) substrate or another substrate. At 604, a nucleation layer (e.g., 104, 204, 304) is deposited. In an MOCVD process, one or more precursors are introduced into the deposition system and decompose, react with each other, and/or react with the substrate to form the nucleation layer. At optional step 606, a stress management layer (e.g., 206, 306) is deposited. In an MOCVD process, one or more precursors are introduced into the deposition system and decompose, react with each other, and/or react with the substrate to form the stress management layer. If no stress management layer is to be included in the layer structure, the method 600 proceeds directly to step 608. At 608, a buffer layer (e.g., 108, 208, 308) is deposited. The buffer layer can be a carbon-doped buffer layer. In an MOCVD process, one or more precursors are introduced into the deposition system and decompose, react with each other, and/or react with the substrate to form the buffer layer. At optional step 610, a back-barrier layer (e.g., 310) is deposited. In an MOCVD process, one or more precursors are introduced into the deposition system and decompose, react with each other, and/or react with the substrate to form the back-barrier layer. If no back-barrier layer is to be included in the layer structure, the method 600 proceeds directly to step 612. At 612, a channel layer (e.g., 112, 212, 312) is deposited. In an MOCVD process, one or more precursors are introduced into the deposition system and decompose, react with each other, and/or react with the substrate to form the channel layer. At 614, a barrier layer (e.g., 116, 216, 316) is deposited. In an MOCVD process, one or more precursors are introduced into the deposition system and decompose, react with each other, and/or react with the substrate to form the barrier layer. At optional step 616, a capping layer is deposited. In an MOCVD process, one or more precursors are introduced into the deposition system and decompose, react with each other, and/or react with the substrate to form the capping layer. If no capping layer is to be included in the layer structure, the method 600 proceeds directly to step 618. At 618, the layer structure and substrate are cooled down.

The precursors used in steps 604, 606, 608, 610, 612, 614, and 616 can be different precursors for each step, or they can be the same precursor for some or all of the steps used in the same or different proportions and/or quantities. In addition, an inert carrier and/or purge gas (e.g., H₂, N₂) can be introduced into the deposition system during any of the above steps.

Intrinsic and/or extrinsic doping can be used in any of steps 604, 606, 608, and 610 to carbon-dope the nucleation layer, the stress management layer, the buffer layer, and the back-barrier layer, respectively. To dope intrinsically, the process parameters are adjusted such that the deposited layer contains carbon from the metalorganic deposition precursors (e.g., trimethylaluminum, trimethylgallium). To dope extrinsically, one or more extrinsic sources such as carbon hydrides (e.g., methane, propane, butane) and carbon halides (e.g., carbon tetrachloride, carbon tetrabromide, bromotrichloromethane) can be introduced into the deposition system during the respective step, along with the precursor(s) for depositing the respective layer.

Steps other than those shown can be performed as part of the method 600. For example, intervening layers can be deposited between any of the layers described in FIG. 6. Steps in the method 600 can be performed in a different order other than the order depicted in FIG. 6. Also, not all of the steps of the method 600 need to be performed. For example, the layer structure 100 can be fabricated using steps 602, 604, 608, 612, 614, and 618. As another example, the layer structure 200 can be fabricated using steps 602, 604, 606, 608, 612, 614, and 618. Furthermore, the layer structure 300 can be deposited using steps 602, 604, 606, 608, 610, 612, 614, 616, and 618.

The growth and/or deposition described herein can be performed using one or more of chemical vapor deposition (CVD), metalorganic chemical vapor deposition (MOCVD), organometallic vapor phase epitaxy (OMVPE), atomic layer deposition (ALD), molecular beam epitaxy (MBE), halide vapor phase epitaxy (HVPE), pulsed laser deposition (PLD), and/or physical vapor deposition (PVD).

As described herein, a layer means a substantially-uniform thickness of a material covering a surface. A layer can be either continuous or discontinuous (i.e., having gaps between regions of the material). For example, a layer can completely cover a surface, or be segmented into discrete regions, which collectively define the layer (i.e., regions formed using selective-area epitaxy). A layer structure means a set of layers, and can be a stand-alone structure or part of a larger structure. A III-nitride structure means a structure containing III-nitride material, and can contain materials other than III-nitrides, a few examples of which are Si, a silicon oxide (SiOₓ), silicon nitride (SiₓN_{y}) and III-V materials.

Disposed on means “exists on” an underlying material or layer. This layer may comprise intermediate layers, such as transitional layers, necessary to ensure a suitable surface. For example, if a material is described to be “disposed on a substrate,” this can mean either (1) the material is in direct contact with the substrate; or (2) the material is in contact with one or more transitional layers that reside on the substrate.

Single-crystal means a crystal structure that comprises substantially only one type of unit-cell. A single-crystal layer, however, may exhibit some crystal defects such as stacking faults, dislocations, or other commonly occurring crystal defects.

Single-domain means a crystalline structure that comprises substantially only one structure of unit-cell and substantially only one orientation of that unit cell. In other words, a single-domain crystal exhibits no twinning or anti-phase domains.

Single-phase means a crystal structure that is both single-crystal and single-domain.

Crystalline means a crystal structure that is substantially single-crystal and substantially single-domain. Crystallinity means the degree to which a crystal structure is single-crystal and single-domain. A highly crystalline structure would be almost entirely, or entirely single-crystal and single-domain.

Epitaxy, epitaxial growth, and epitaxial deposition refer to growth or deposition of a crystalline layer on a crystalline substrate. The crystalline layer is referred to as an epitaxial layer. The crystalline substrate acts as a template and determines the orientation and lattice spacing of the crystalline layer. The crystalline layer can be, in some examples, lattice matched or lattice coincident. A lattice matched crystalline layer can have the same or a very similar lattice spacing as the top surface of the crystalline substrate. A lattice coincident crystalline layer can have a lattice spacing that is an integer multiple, or very similar to an integer multiple, of the lattice spacing of the crystalline substrate. Alternatively, the lattice spacing of the crystalline substrate can be an integer multiple, or very similar to an integer multiple, of the lattice spacing of the lattice coincident crystalline layer. The quality of the epitaxy is based in part on the degree of crystallinity of the crystalline layer. Practically, a high quality epitaxial layer will be a single crystal with minimal defects and few or no grain boundaries.

Substrate means the material on which deposited layers are formed. Exemplary substrates include, without limitation: bulk silicon wafers, in which a wafer comprises a homogeneous thickness of single-crystal silicon; composite wafers, such as a silicon-on-insulator wafer that comprises a layer of silicon that is disposed on a layer of silicon dioxide that is disposed on a bulk silicon handle wafer; or any other material that serves as base layer upon which, or in which, devices are formed. Examples of such other materials that are suitable, as a function of the application, for use as substrate layers and bulk substrates include, without limitation, gallium nitride, silicon carbide, gallium oxide, germanium, alumina, gallium-arsenide, indium-phosphide, silica, silicon dioxide, borosilicate glass, pyrex, and sapphire.

REO substrate means a composition that comprises a single crystal rare earth oxide layer and a substrate. Examples of the rare earth oxides are gadolinium oxide (Gd₂O₃), erbium oxide (Er₂O₃) and ytterbium oxide (Yb₂O₃). The substrate consists of Si (100), Si (111) or other suitable materials. The rare earth oxide layer is epitaxially deposited on the substrate.

Semiconductor-on-Insulator means a composition that comprises a single-crystal semiconductor layer, a single-phase dielectric layer, and a substrate, wherein the dielectric layer is interposed between the semiconductor layer and the substrate. This structure is reminiscent of prior-art silicon-on-insulator (“SOI”) compositions, which typically include a single-crystal silicon substrate, a non-single-phase dielectric layer (e.g., amorphous silicon dioxide, etc.) and a single-crystal silicon semiconductor layer. Several important distinctions between prior-art SOI wafers and the inventive semiconductor-on-insulator compositions are that:

Semiconductor-on-insulator compositions include a dielectric layer that has a single-phase morphology, whereas SOI wafers do not. In fact, the insulator layer of typical SOI wafers is not even single crystal.

Semiconductor-on-insulator compositions include a silicon, germanium, or silicon-germanium “active” layer, whereas prior-art SOI wafers use a silicon active layer. In other words, exemplary semiconductor-on-insulator compositions include, without limitation: silicon-on-insulator, germanium-on-insulator, and silicon-germanium-on-insulator.

A first layer described and/or depicted herein as “on” or “over” a second layer can be immediately adjacent to the second layer, or one or more intervening layers can be between the first and second layers. An intervening layer described and/or depicted as “between” first and second layers can be immediately adjacent to the first and/or the second layers, or one or more additional intervening layers may be between the intervening layer and the first and second layers. A first layer that is described and/or depicted herein as “directly on” or “directly over” a second layer or a substrate is immediately adjacent to the second layer or substrate with no intervening layer present, other than possibly an intervening alloy layer that may form due to mixing of the first layer with the second layer or substrate. In addition, a first layer that is described and/or depicted herein as being “on,” “over,” “directly on,” or “directly over” a second layer or substrate may cover the entire second layer or substrate, or a portion of the second layer or substrate.

A substrate is placed on a substrate holder during layer growth, and so a top surface or an upper surface is the surface of the substrate or layer furthest from the substrate holder, while a bottom surface or a lower surface is the surface of the substrate or layer nearest to the substrate holder. Any of the structures depicted and described herein can be part of larger structures with additional layers above and/or below those depicted. For clarity, the figures herein can omit these additional layers, although these additional layers can be part of the structures disclosed. In addition, the structures depicted can be repeated in units, even if this repetition is not depicted in the figures.

From the above description it is manifest that various techniques may be used for implementing the concepts described herein without departing from the scope of the disclosure. The described embodiments are to be considered in all respects as illustrative and not restrictive. It should also be understood that the techniques and structures described herein are not limited to the particular examples described herein, but can be implemented in other examples without departing from the scope of the disclosure. Similarly, while operations are depicted in the drawings in a particular order, this should not be understood as requiring that such operations be performed in the particular order shown or in sequential order, or that all illustrated operations be performed, to achieve desirable results. Additionally, the different examples described are not singular examples and features from one example may be included within the other disclosed examples. Accordingly, it will be understood that the claims are not to be limited to the examples disclosed herein, but is to be understood from the technical teachings provided above, as those teachings will inform the person of skill in the art.

What is claimed is:

1. A III-nitride structure, comprising:
a silicon substrate;
a nucleation layer over the silicon substrate;
a carbon-doped buffer layer over the nucleation layer, wherein the carbon-doped buffer layer comprises:
a III-nitride material, and
a concentration of carbon that is greater than 1×10²⁰ cm⁻³;
a III-nitride channel layer over the carbon-doped buffer layer; and
a III-nitride barrier layer over the III-nitride channel layer.

2. The III-nitride structure of claim 1, wherein an average dislocation density of the carbon-doped buffer layer is less than 1×10¹² cm⁻².

3. The III-nitride structure of claim 1, wherein each of the nucleation layer, the carbon-doped buffer layer, the III-nitride channel layer, and the III-nitride barrier layer is epitaxial.

4. The III-nitride structure of claim 1, wherein the carbon-doped buffer layer comprises AlₓGa₁₋ₓN, where 0≦x≦1.

5. The III-nitride structure of claim 1, further comprising a stress management layer between the nucleation layer and the carbon-doped buffer layer.

6. The III-nitride structure of claim 5, wherein the stress management layer comprises a concentration of carbon that is greater than 1×10²⁰ cm⁻³.

7. The III-nitride structure of claim 6, wherein the stress management layer comprises a multiple layer structure.

8. The III-nitride structure of claim 7, wherein the multiple layer structure comprises alternating layers of AlₓGa₁₋ₓN and GaN, where 0≦x≦1.

9. The III-nitride structure of claim 1, wherein the III-nitride channel layer comprises GaN.

10. The III-nitride structure of claim 1, wherein the barrier layer comprises AlₓGa₁₋ₓN, where 0≦x≦1.

11. The III-nitride structure of claim 10, wherein the nucleation layer comprises a concentration of carbon that is greater than 1×10²⁰ cm⁻³.

12. The III-nitride structure of claim 5, further comprising:
a III-nitride back-barrier layer between the carbon-doped buffer layer and the III-nitride channel layer; and
a capping layer over the barrier layer.

13. The III-nitride structure of claim 12, wherein the back-barrier layer comprises a concentration of carbon that is greater than 1×10²⁰ cm⁻³.

14. A method of fabricating a III-nitride structure, comprising:
depositing a nucleation layer over a silicon substrate;
depositing a carbon-doped buffer layer over the nucleation layer, wherein the carbon-doped buffer layer comprises:
a III-nitride material, and
a concentration of carbon that is greater than 1×10²⁰ cm⁻³;
depositing a III-nitride channel layer over the carbon-doped buffer layer; and
depositing a III-nitride barrier layer over the III-nitride channel layer.

15. The method of claim 14, wherein an average dislocation density of the carbon-doped buffer layer is less than 1×10¹² cm⁻².

16. The method of claim 14, wherein each of the nucleation layer, the carbon-doped buffer layer, the III-nitride channel layer, and the III-nitride barrier layer is epitaxial.

17. The method of claim 14, comprising using an extrinsic source of carbon for depositing the carbon-doped buffer layer.

18. The method of claim 17, wherein the extrinsic source of carbon comprises a carbon hydride.

19. The method of claim 17, wherein the extrinsic source of carbon comprises a carbon halide.

20. The method of claim 14, wherein the carbon-doped buffer layer comprises AlₓGa₁₋ₓN, where 0≦x≦1.

21. The method of claim 14, further comprising depositing a stress management layer between the nucleation layer and the carbon-doped buffer layer.

22. The method of claim 21, wherein the stress management layer comprises a concentration of carbon that is greater than 1×10²⁰ cm⁻³.

23. The method of claim 22, wherein the stress management layer comprises a multiple layer structure.

24. The method of claim 23, wherein the multiple layer structure comprises alternating layers of AlₓGa₁₋ₓN and GaN, where 0≦x≦1.

25. The method of claim 14, wherein the III-nitride channel layer comprises GaN.

26. The method of claim 14, wherein the barrier layer comprises AlₓGa₁₋ₓN, where 0≦x≦1.

27. The method of claim 26, wherein the nucleation layer comprises a concentration of carbon that is greater than 1×10²⁰ cm⁻³.

28. The method of claim 21, further comprising:
depositing a III-nitride back-barrier layer between the carbon-doped buffer layer and the III-nitride channel layer; and
depositing a capping layer over the barrier layer.

29. The method of claim 28, wherein the back-barrier layer comprises a concentration of carbon that is greater than 1×10²⁰ cm⁻³.
